(19) United States
(12) Patent Application Publication
(10) Pub. No.: US 2006/0220112 A1
(43) Pub. Date: Oct. 5, 2006

(54) SEMICONDUCTOR DEVICE FORMING METHOD AND STRUCTURE FOR RETARDING DOPANT-ENHANCED DIFFUSION

(75) Inventors: Huilong Zhu, Poughkeepsie, NY (US); Kam-Leung Lee, Putnam Valley, NY (US); Jinghong Li, Poughquag, NY (US); Anda C. Mocuta, LaGrangeville, NY (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, Armonk (US)

(21) Appl. No.: 10/907,464

(22) Filed: Apr. 1, 2005

(51) Int. Cl. H01L 29/76

(52) U.S. Cl. 257/335; 257/E29.049

(57) ABSTRACT

Methods and structure formed for retarding diffusion of a dopant into a channel of a strained Si—SiGe CMOS device are disclosed. The methods form a diffusion retardant region in a substrate including at least one diffusion retardant species such as xenon (Xe), and then form a channel layer over the diffusion retardant region. Each step is conducted prior to formation of a gate on the substrate. As a result, if necessary, the diffusion retardant region can be annealed and cleaned or etched to remove defects in the substrate to reduce external resistance and leakage of devices. The diffusion retardant region positioned under the channel slows down the diffusion of a dopant, e.g., arsenic (As). The invention is also applicable to other substrates.

### BACKGROUND OF THE INVENTION

1. Technical Field

The present invention relates generally to semiconductor device fabrication, and more particularly to a method and structure for retarding dopant-enhanced diffusion in strained silicon/silicon-germanium (SSi/SiGe) substrates by implanting a diffusion retardant in the substrate.

2. Related Art

Strained silicon (Si) complementary metal oxide semiconductor (CMOS) devices with a strained Si channel on a relaxed silicon-germanium (SiGe) buffer layer offer better device performance over conventional Si CMOS because of the enhancement in both channel electron and hole mobilities, and have been demonstrated for devices as small as about 60 nm. However, for devices at about 60 nm or below, an extension junction depth (Xj) 30 nm or below would be needed. The diffusion of a dopant in SiGe can form parasitic barriers at the heterojunction in a heterojunction bipolar transistor (HBT). More importantly, the junction slope (Xjs) near the channel region should be abrupt (<6 nm/decade), and the dopant concentration at the extension should be approximately 1 E20/cm³.

However, as described in co-pending application, entitled “Method for Slowing Down Dopant-enhanced Diffusion Substrates and Devices Fabricated Therefrom,” U.S. Ser. No. 10/627,753, filed Jul. 28, 2003, which is hereby incorporated by reference, shallow junction requirements are difficult to achieve for a dopant (e.g., arsenic) junction in N-type metal oxide semiconductor (NMOS) devices in strained Si—SiGe substrates due to significant arsenic-enhanced diffusion. That is, experimentally, it has been found that arsenic dopant diffusivity increases exponentially with the percentage of the germanium (Ge) content in the strained Si—Si₁₋ₓGeₓ buffer layer. Thus, enhanced arsenic dopant diffusion in strained Si—SiGe substrates becomes a significant roadblock for generating ultra-shallow junctions for a small (e.g., about sub-50 nm) NMOS device in strained Si substrates where high %Ge (e.g., >about 20%) is used for higher electron and hole mobility for improved device performance. In addition, for a sub-50 nm device, the enhanced lateral arsenic dopant diffusion will short-circuit the source and drain regions of the NMOS device, and will render the device totally inoperable. That is, high arsenic dopant concentrations are immediately below the center of the gate (e.g., a polysilicon gate). This high concentration of dopant underneath the gate creates shorting due to enhanced arsenic junction diffusion from the extension junction region to the gate region. There had been no known techniques (or resulting structures) for slowing down the arsenic enhanced diffusion in strained Si/SiGe or strained Si₁₋ₓGeₓ/Si device substrates prior to the co-pending application.

In order to address this situation, the co-pending application discloses co-implanting, i.e., implanting in series, a dopant and a species to slow diffusion. In that application, the gate was already formed and used to protect the channel. It has now been recognized, however, that the co-implantation through the strained silicon cap causes defects, which increases external resistance and leakage. In addition, due to Ge and dopant diffusion into the silicon cap and channel area, the strained Si—SiGe substrate cannot withstand high temperature anneals to remove implantation damage.

In view of the foregoing, there is a need in the art for an improved method and structure so formed to address the problems of the related art.

### SUMMARY OF THE INVENTION

The invention includes methods and a structure formed for retarding diffusion of a dopant into a channel of a strained Si—SiGe CMOS device. The methods form a diffusion retardant region in a substrate including at least one diffusion retardant species such as xenon (Xe), and then form a channel over the diffusion retardant region. Each step is conducted prior to formation of a gate on the substrate. As a result, if necessary, the diffusion retardant region can be annealed and cleaned or etched to remove defects in the substrate to reduce external resistance and leakage of devices. The diffusion retardant region positioned under the channel slows down the diffusion of dopant, e.g., arsenic (As). The invention is also applicable to other substrates.

A first aspect of the invention is directed to a method of forming a semiconductor device, the method comprising the steps of: forming a diffusion retardant region in a substrate, the region including at least one diffusion retardant species; and forming a channel layer over the diffusion retardant region, wherein each step is conducted prior to formation of a gate on the substrate.

A second aspect of the invention includes a semiconductor device comprising: a semiconductor substrate; a dopant formed in the substrate to define a channel; and a region formed under the channel, the region including at least one diffusion retardant species for retarding a diffusion of the dopant during formation of a gate over the channel.

A third aspect of the invention is related to a method of forming a semiconductor device, the method comprising the steps of: prior to formation of a gate on a substrate: a) forming a region in the substrate including at least one diffusion retardant species; b) annealing the substrate; c) forming a strained silicon layer over the substrate; and forming a channel over the region in the strained silicon layer.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIGS. 1-5 show steps of a method according to the invention.

FIG. 6 shows a CMOS device formed according to the method of FIGS. 1-5.

### DETAILED DESCRIPTION

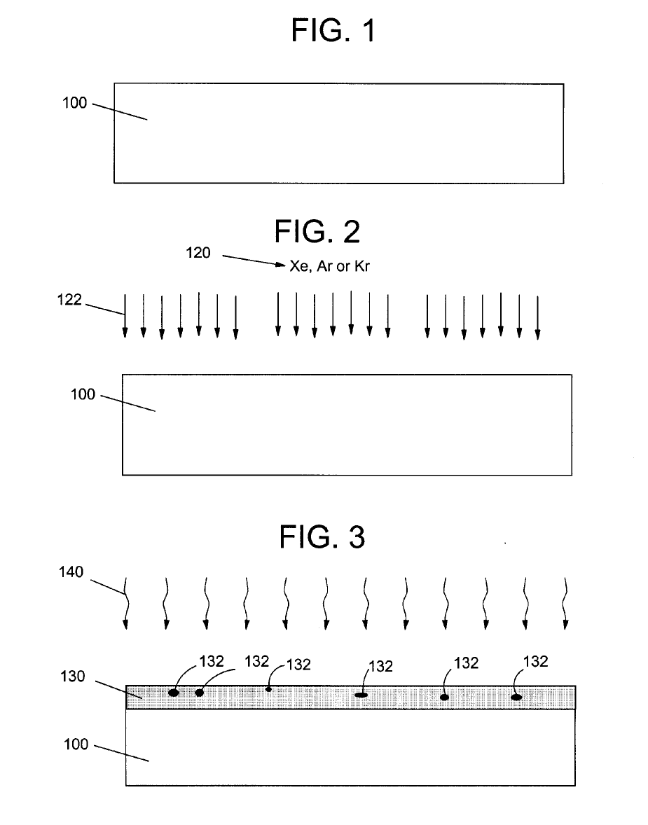

With reference to the accompanying drawings, FIG. 1 illustrates a starting structure for methods according to the invention including a substrate 100. In one embodiment, substrate 100 includes a silicon-germanium (SiGe) bulk substrate or a SiGe-on-insulator substrate (insulator not shown). However, substrate 100 may also include pure bulk silicon, as will be described below.

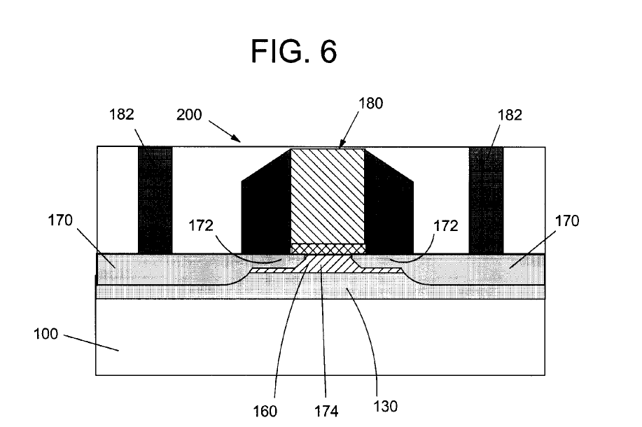

FIGS. 2-5 illustrate various steps of the inventive method. A feature of the steps shown in FIGS. 2-5 is that they all occur prior to fabrication of a device 200, e.g., a gate, as shown in FIG. 6. The significance of this feature will be described below.

In a first step, as shown in FIG. 2, a diffusion retardant region 130 (FIG. 3) is formed in substrate 100 including at least one diffusion retardant species 120 (Z). That is, a Si_{1-x-y}GeₓZ_{y} region 130 is formed, where Z is the diffusion retardant species. In one preferred embodiment, species 120 is implanted 122. However, diffusion retardant region 130 may also be formed by in-situ growing diffusion retardant species 120 with substrate 100. In one embodiment, diffusion retardant species 120 includes xenon (Xe). However, diffusion retardant species 120 may be any element capable of slowing down diffusion of a dopant into a channel of the device to be generated subsequently. In this regard, argon (Ar) or krypton (Kr) may be substituted. The depth of diffusion retardant region 130 in substrate 100 is to be selected to accommodate the desired depth of the junction for the device to be generated. In one embodiment, the depth is approximately 50 nm to approximately 200 nm.

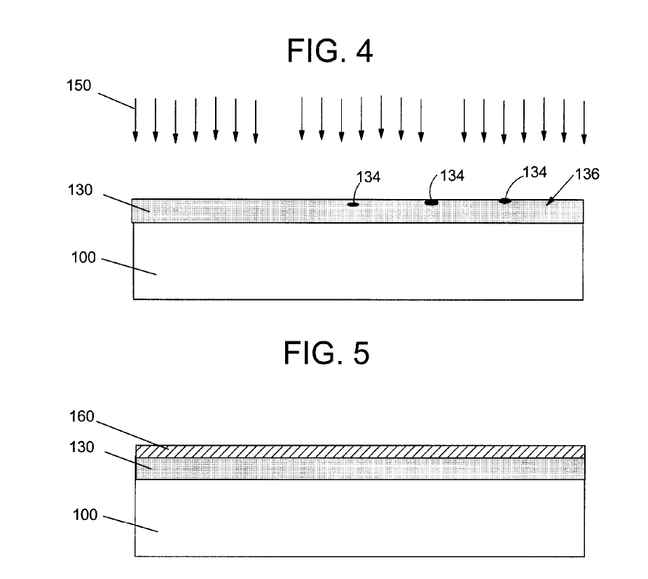

As shown in FIG. 3, diffusion retardant region 130 may include defects 132 caused by diffusion retardant species 120 (FIG. 2). When this occurs, as shown in FIG. 3, a high temperature anneal 140 of substrate 100 can be conducted to remove at least some of defects 132. Anneal 140 may have a temperature of approximately 950° C. to approximately 1100° C. As shown in FIG. 4, some defects 134 may remain near an upper region 136 of substrate 100, e.g., at a depth of approximately 5 nm to a depth of approximately 10 nm. If defects 134 remain, the method can further include the step of removing the defects by conducting a clean and/or etch 150, as shown in FIG. 4. A clean may include any standard cleaning process to remove native oxide, etc., such as potassium hydroxide (KOH). An etch may include, for example, a reactive ion etch.

Next, as shown in FIG. 5, a channel layer 160 is formed over diffusion retardant region 130. In one embodiment, channel layer 160 includes strained silicon and is formed, for example, by epitaxial growth. Channel layer 160 has a thickness of the desired channel, e.g., preferably about 100 Å to about 200 Å.

As shown in finished form in FIG. 6, conventional processing steps continue hereafter to generate a strained Si—SiGe CMOS device 200. One step includes implanting a dopant, e.g., arsenic (As), to form source and drain regions 170 and/or source/drain extensions 172 in channel layer 160 and form channel 174 adjacent thereto. Another step includes forming a gate 180 over channel 174. Diffusion retardant region 130 is formed under channel 174. Contacts 182 may also be formed over source and drain regions 170. Other conventional processing recognized to those skilled in the art and not shown may also be included. The finishing processing may occur in any order desired.

Due to the formation of diffusion retardant region 130, dopant-enhanced diffusion of, e.g., arsenic, into channel 174 is retarded during high temperature annealing steps conducted during device formation. The method prevents dopant diffusion in strained Si—SiGe substrates from becoming a significant roadblock for generating ultra-shallow junctions for a small NMOS device in strained Si substrates where a high percentage high of germanium (Ge) is used (e.g., > about 20%). In addition, short-circuiting of the source and drain regions of an NMOS device for a sub-50 nm devices is avoided. Since diffusion retardant region 130 is formed prior to device formation processing, defects caused by the creation of the region can be easily removed and high temperature anneals occur prior to the formation of the channel layer 160.

In an alternative embodiment, the above-described method is carried out using a pure bulk silicon substrate 100. That is, the diffusion retardant species 120 (FIG. 2) is implanted into a pure silicon substrate, followed by a high temperature anneal to eliminate defects and potentially clean or etch. A channel layer 160 (FIGS. 4-6) may then be formed using silicon to obtain good channel mobility and small leakage.

The above-described methods provide a mechanism to retard dopant-enhanced diffusion.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1. A method of forming a semiconductor device, the method comprising the steps of:
forming a diffusion retardant region in a substrate, the region including at least one diffusion retardant species; and
forming a channel layer over the diffusion retardant region,
wherein each step is conducted prior to formation of a gate on the substrate.

2. The method of claim 1, wherein the diffusion retardant region forming step includes:
conducting one of: a) implanting the diffusion retardant species into the substrate, and b) in-situ growing the diffusion retardant species with the substrate; and
annealing the substrate.

3. The method of claim 2, further comprising the step of removing at least one defect from an upper region of the substrate by conducting at least one of a clean and an etch

4. The method of claim 1, wherein the at least one diffusion retardant species comprises at least one of: xenon (Xe), argon (Ar) and krypton (Kr).

5. The method of claim 1, wherein the diffusion retardant region has a depth of no less than approximately 50 nm and no greater than approximately 200 nm, in the substrate.

6. The method of claim 1, wherein the channel layer forming step includes:
epitaxially growing a strained silicon layer; and
implanting a dopant to form a source and drain region to form a channel from the channel layer.

7. The method of claim 6, wherein the dopant includes arsenic (As).

8. The method of claim 1, wherein the channel layer has a thickness of no less than 100 Å and no more than 200 Å.

9. The method of claim 1, wherein the substrate includes one of silicon and relaxed silicon-germanium.

10. A semiconductor device comprising:
a semiconductor substrate;
a dopant formed in the substrate to define a channel; and
a region formed under the channel, the region including at least one diffusion retardant species for retarding a diffusion of the dopant during formation of a gate over the channel.

11. The device of claim 10, further comprising:
a source region and a drain region adjacent to the channel;
a gate formed over the channel; and
a contact formed over the source and drain regions.

12. The device of claim 10, wherein the channel has a thickness of no less than 100 Å and no more than 200 Å, and the region has a depth of no less than approximately 50 nm and no greater than approximately 200 nm, in the substrate.

13. The device of claim 10, wherein the at least one diffusion retardant species comprises xenon (Xe), or argon (Ar) or krypton (Kr).

14. The device of claim 10, wherein the channel includes strained silicon, and the dopant includes arsenic (As).

15. The device of claim 10, wherein the semiconductor substrate includes silicon or relaxed silicon-germanium.

16. A method of forming a semiconductor device, the method comprising the steps of:
prior to formation of a gate on a substrate:
a) forming a region in the substrate including at least one diffusion retardant species;
b) annealing the substrate;
c) forming a strained silicon layer over the substrate; and
forming a channel over the region in the strained silicon layer.

17. The method of claim 16, wherein the substrate includes relaxed silicon-germanium; and
wherein the region forming step includes conducting one of: a) implanting the diffusion retardant species into the substrate.

18. The method of claim 16, further comprising the step of removing at least one defect from an upper region of the substrate by conducting at least one of a clean and an etch.

19. The method of claim 16, wherein the at least one diffusion retardant species comprises at least one of: xenon (Xe), argon (Ar) and krypton (Kr).

20. The method of claim 16, wherein the diffusion retardant region has a depth of no less than approximately 50 nm and no greater than approximately 200 nm in the substrate; and the channel has a thickness of no less than 100 Å and no more than 200 Å.
